(19) United States
(12) Patent Application Publication
(10) Pub. No.: US 2005/0146050 A1
(43) Pub. Date: Jul. 7, 2005

(54) FLIP CHIP PACKAGE STRUCTURE AND CHIP STRUCTURE THEREOF

(76) Inventors: Yu-Wen Chen, Sanmin Chiu (TW); Chi-Hao Chiu, Pingdung City (TW); Chung-Yao Kao, Pingtung County (TW); Ming-Chieh Kao, Kaohsiung City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/904,512

(22) Filed: Nov. 14, 2004

(30) Foreign Application Priority Data
Nov. 14, 2003 (TW) 92131927

(51) Int. Cl. H01L 21/44

(52) U.S. Cl. 257/778

(57) ABSTRACT

The present invention provides a flip chip package structure comprising a substrate, a chip and a plurality ofbumps. A plurality of contacts is disposed on the carrying surface and the chip is disposed on the carrying surface of the substrate. The chip includes an active surface and a plurality of bonding pads. The active surface of the chip comprises a bumping region and a plurality of non-bumping regions at corners of the chip, while the bonding pads are disposed within the bumping region of the active surface of the chip. The bumps, respectively disposed on the bonding pads, electrically and mechanically connect the contacts and the bonding pads.

### CROSS-REFERENCE TO RELATED APPLICATION

This application claims the priority benefit of Taiwan application Serial no. 92131927, filed on Nov. 14, 2003.

### BACKGROUND OF THE INVENTION

1. Field of Invention

The present invention relates to a package structure. More particularly, the present invention relates to a flip chip package structure and a chip structure thereof, with better connection between the chip and the substrate.

2. Description of Related Art

In the semiconductor industry, integrated circuits (ICs) manufacture can be categorized as three major stages: fabrication of the wafers, fabrication of the ICs and packaging of the ICs. Through wafer preparation, circuitry design, mask fabrication and wafer dicing, the bare dies are obtained. Each die has bonding pads for outwardly electrical connections. By using the molding materials to achieve the encapsulation of the die, the die is protected from the influences of moisture, heat and noises. The package of the die can provide the medium for electrical connection between the die and the outward circuit.

In FC packaging technology, the arrangement of area arrays is mainly employed. The chip (die) having bonding pads disposed on the active surface of the chip is provided, and bumps are formed on the bonding pads of the chip. After flipping over the chip and arrange the active surface of the chip to the substrate, the bumps are electronically and mechanically connected to the contacts of the substrate and further connected to the external electronic devices through the internal wiring of the substrate.

However, as the operation speed of the chip becomes faster and the operation temperature becomes higher, the thermal stress resulting from the mismatch of coefficients of thermal expansion (CTE) between the chip and the substrate becomes larger. During thermal cycles, the large thermal stress may cause bumps break or peel from the chip and even result in warpage deformation of the package structure. It is noted that the bumps farther from the center of the chip bear the larger thermal stress and are easily demolished. Based on the principle of stress distribution and the observations, the bumps disposed at the corners of the chip are most easily defective.

### SUMMARY OF THE INVENTION

The present invention provides a flip chip package structure and a chip structure, which enhances connection between the chip and the substrate by reducing damages of the bumps or the package structure resulting from thermal stress.

As embodied and broadly described herein, a flip chip package structure comprising a substrate, a chip and a plurality of bumps is provided. A plurality of contacts is disposed on the carrying surface and the chip is disposed on the carrying surface of the substrate. The chip includes an active surface and a plurality of bonding pads. The active surface of the chip comprises a bumping region and a plurality of non-bumping regions at corners of the chip, while the bonding pads are disposed within the bumping region of the active surface of the chip. The bumps, respectively disposed on the bonding pads, electrically and mechanically connect the contacts and the bonding pads.

The present invention also provides a chip having an active surface and a plurality of bonding pads. The active surface of the chip comprises a plurality of non-bumping regions at corners of the chip and a bumping region. Except for the non-bumping regions, the other regions of the active surface of the chip are considered as a bumping region. The bonding pads are disposed within the bumping region of the active surface of the chip.

The bonding pads are distributed evenly in the bumping region using a center of the active surface as a distribution center. The non-bumping region can be in a rectangular shape or in a fan shape, for example. Besides, the bumping region can be in a circular or cross shape, for example.

The above structures may further include a central non-bumping region at the center of the chip. The central non-bumping region can be in a rectangular shape or in a circular shape, for example.

According to the present invention, through carefully arranging the positions of the bonding pads (or bumps), the bumps are disposed within the predetermined bumping region and are away from the corners of the chip. Hence, the resultant package structure affords better connection between the chip and the substrate and improves the reliability of the bumps and the quality of the package structure.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A is a cross-sectional display view illustrating a flip chip package structure according to the first preferred embodiment of this invention.

FIG. 1B is a top display view illustrating a flip chip package structure according to the first preferred embodiment of this invention.

FIG. 2 is a top display view illustrating a flip chip package structure according to the second preferred embodiment of this invention.

FIG. 3 is a top display view illustrating a flip chip package structure according to the third preferred embodiment of this invention.

FIG. 4 is a top display view illustrating a flip chip package structure according to the fourth preferred embodiment of this invention.

FIG. 5 is a top display view illustrating a flip chip package structure according to the fifth preferred embodiment of this invention.

### DESCRIPTION OF THE PREFERRED EMBODIMENTS

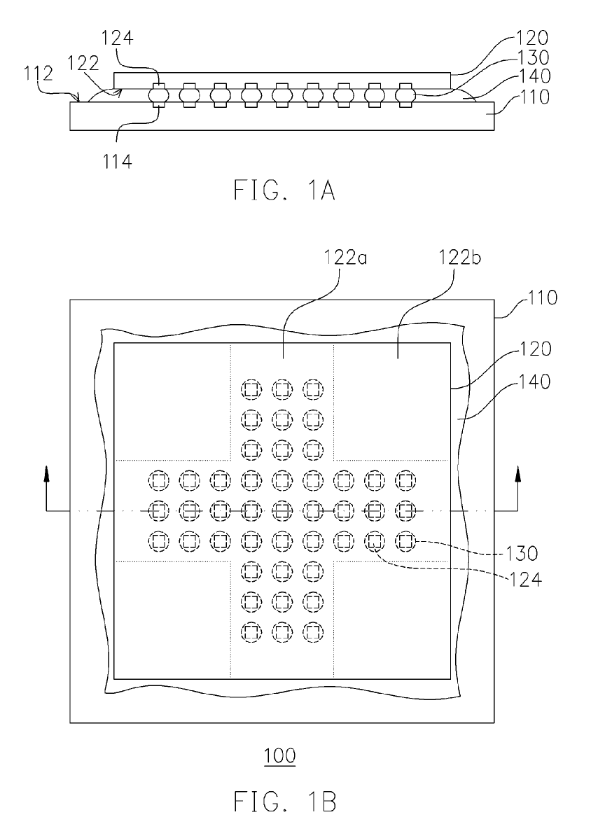

FIG. 1A is a cross-sectional display view illustrating a flip chip package structure according to the first preferred embodiment of this invention, while FIG. 1B is a top display view illustrating a flip chip package structure according to the first preferred embodiment of this invention. Referring to FIG. 1A, the flip chip package structure 100 includes a chip 120 disposed on a substrate 110. A carrying surface 112 of the substrate 110 are electrically connected to an active surface 122 of the chip 120 through bumps 130. An underfill 140 is filled between the chip 120 and the substrate 110 and wraps the bumps 130. A plurality of contacts 114 is disposed on the carrying surface 112 of the substrate 110.

Referring to FIG. 1B, a rectangular region at each corner of the active surface 122 is arranged as a non-bumping region 122b, while the other regions of the active surface 122 are arranged as a bumping region 122a. A plurality of bonding pads 124 are disposed on the active surface 122 and distributed evenly within the bumping region 122a using the center of the active surface 122 as the distribution center. A plurality of bumps 130 is disposed on the bonding pads 124 respectively. The bumps 130 electrically and mechanically connect the bonding pads 124 and the contacts 114, thus connecting the chip 120 and the substrate 110.

For the above structure 100, the four corners of the active surface 122 with larger thermal stress are arranged as the non-bumping regions 122b. Moreover, the bonding pads 124 are evenly distributed within the bumping region 122a from the center of the chip. Hence, as the chip 120 is connected to the substrate 110, the bumps 130 will not be disposed around the corners of the chip 120. Therefore, possibilities of bump peeling due to large thermal stress are greatly reduced.

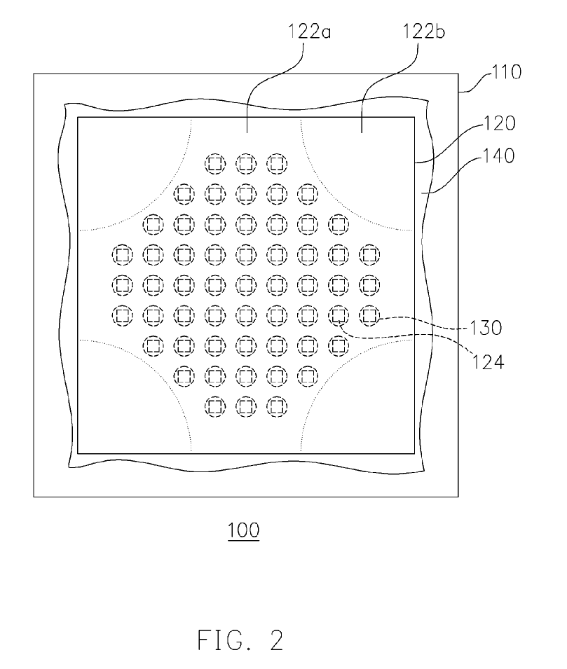

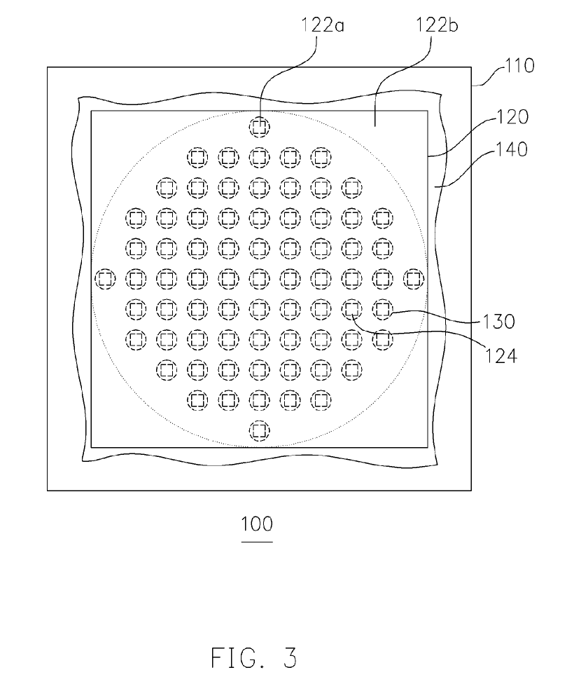

It is emphasized that the shapes of the non-bumping regions are not limited to rectangular as described in the above structure, but can be various shapes including triangular or fan shapes (as shown in FIG. 2). Also, the shape of the bumping region is not limited to the cross shape (as shown in FIG. 1B); still, the bumping region can be designed to be a circular or ring-shaped region as shown in FIG. 3.

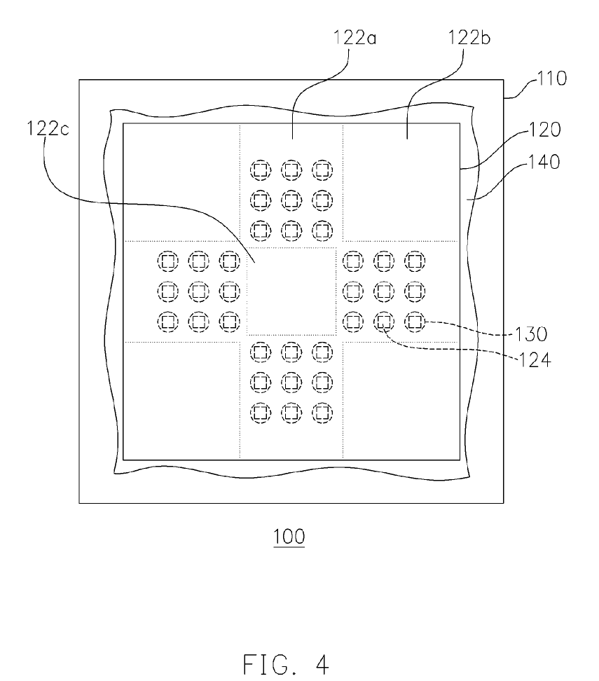

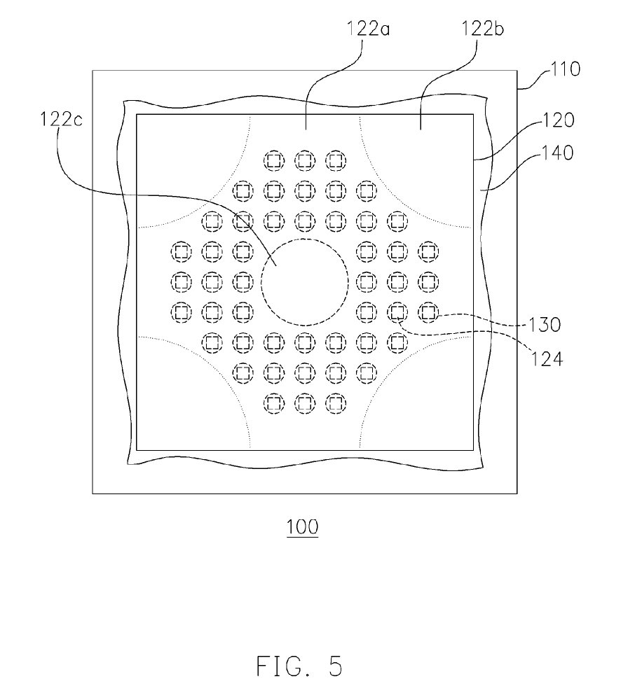

Depending on the numbers of the bumps and the electrical requirements of the chip or the substrate, the shapes of the non-bumping region(s) or the bumping region can be altered. FIGS. 4-5 are top display views illustrating flip chip package structures according to the preferred embodiments of this invention. Similar to the flip-chip package structure 100 of FIG. 1A, the flip chip package structure in FIG. 4 further includes an extra non-bumping region 122c at the center of the chip 120. The shape of the central non-bumping region 122c can be designed to be rectangular (as shown in FIG. 4) or circular (as shown in FIG. 5). As discussed above, the other non-bumping regions can have shapes different to that of the central non-bumping region. As shown in FIG. 5, the non-bumping regions 122b at the four corners are in fan shapes, while the central non-bumping region 122c is in a circular shape.

From the above embodiments, through carefully arranging the positions of the bonding pads (or bumps), the bumps are disposed within the predetermined bumping region and are away from the corners of the chip. By doing so, the stress borne by the bumps is precisely controlled not to exceed the tolerable stress for the bumps, which effectively avoids peeling of the bumps. Hence, the connection strength between the chip and the substrate is maintained and the reliability of the connection between the chip and the substrate is improved.

According to this invention, not only the size or shapes of the non-bumping regions or bumping regions can be adjusted, the relative positions of the non-bumping regions and bumping regions can be changed to have the best connection strength.

As the package structure of this invention is exposed to high temperature, the flip chip package structure described above can prevent bump peeling, induced by thermal stress. Thus, the package structure provided herein could afford better connection between the chip and the substrate and improve the reliability of the bumps and the quality of the package structure.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

1. A flip chip package structure, comprising:
a substrate having a first surface, wherein a plurality of contacts is disposed on the first surface;
a chip disposed on the first surface of the substrate and having an active surface and a plurality of bonding pads, wherein the active surface of the chip comprises a plurality of first non-bumping regions at corners of the chip,
wherein except for the non-bumping regions the active surface of the chip is a bumping region and the bonding pads are disposed within the bumping region of the active surface of the chip; and
a plurality of bumps, respectively disposed on the bonding pads, wherein the bumps electrically and mechanically connect the contacts and the bonding pads.

2. The structure of claim 1, wherein the first non-bumping region is in a rectangular shape.

3. The structure of claim 1, wherein the first non-bumping region is in a fan shape.

4. The structure of claim 1, wherein the bumping region is in a circular shape.

5. The structure of claim 1, wherein the active surface of the chip further comprises a second non-bumping region at a center of the chip.

6. The structure of claim 5, wherein the second non-bumping region is in a rectangular shape.

7. The structure of claim 5, wherein the second non-bumping region is in a circular shape.

8. The structure of claim 1, wherein the bonding pads are distributed evenly in the bumping region using a center of the active surface as a distribution center.

9. The structure of claim 1, further comprising an underfill between the chip and the substrate and wrapping the bumps.

10. A chip structure, comprising:
a chip having an active surface and a plurality of bonding pads, wherein the active surface of the chip comprises a plurality of first non-bumping regions at corners of the chip, wherein except for the non-bumping regions the active surface of the chip is a bumping region; and
a plurality of bonding pads disposed within the bumping region of the active surface of the chip.

11. The structure of claim 10, wherein the non-bumping region is in a rectangular shape.

12. The structure of claim 10, wherein the non-bumping region is in a fan shape.

13. The structure of claim 10, wherein the active surface of the chip further comprises a second non-bumping region at a center of the chip.

14. The structure of claim 13, wherein the second non-bumping region is in a rectangular shape.

15. The structure of claim 13, wherein the second non-bumping region is in a circular shape.

16. The structure of claim 10, wherein the bumping region is in a circular shape.

17. The structure of claim 10, wherein the bonding pads are distributed evenly in the bumping region using a center of the active surface as a distribution center.

18. A flip chip package structure, comprising:
a substrate having a carrying surface, wherein a plurality of contacts is disposed on the carrying surface;
a chip disposed on the carrying surface of the substrate and having an active surface and a plurality of bonding pads, wherein the active surface of the chip comprises a bumping region, a central non-bumping region disposed on a center of the chip and at least a non-bumping region at a corner of the chip, wherein the bonding pads are disposed within the bumping region of the active surface of the chip; and
a plurality of bumps, respectively disposed on the bonding pads, wherein the bumps electrically and mechanically connect the contacts and the bonding pads.

19. The structure of claim 18, wherein a shape of the non-bumping region is rectangular or fan-shaped.

20. The structure of claim 18, wherein a shape of the central non-bumping region is circular or rectangular.
